(19) United States
(12) Patent Application Publication
(10) Pub. No.: US 2011/0286281 A1
(43) Pub. Date: Nov. 24, 2011

(54) REFERENCE CURRENT GENERATOR USED FOR PROGRAMMING AND ERASING OF NON-VOLATILE MEMORY

(75) Inventor: HSIN CHANG LIN, HSIN-CHU COUNTY (TW)

(73) Assignee: YIELD MICROELECTRONICS CORP., HSIN-CHU COUNTY (TW)

(21) Appl. No.: 12/784,712

(22) Filed: May 21, 2010

(51) Int. Cl. G11C 16/06

(52) U.S. Cl. 365/185.21

(57) ABSTRACT

A reference current generator used for programming and erasing of the non-volatile memory. Wherein, a self-biasing reference generator is used to generate a first reference voltage of a negative temperature coefficient and a second reference voltage of a positive temperature coefficient. A voltage converter receives said first reference voltage and generate a third reference voltage having its temperature coefficient less than that of said first reference voltage, and said second reference voltage and said third reference voltage are input to a reference current source, such that said reference current source generates a reference current of low temperature sensitivity. Through said reference current source, said second reference voltage and said third reference voltage are used to compensate said negative temperature coefficient of a threshold voltage of a transistor, thus reducing difference of times required for programming and erasure under various operation temperatures.

### BACKGROUND OF THE INVENTION

1. Field of the Invention

The present invention relates to a reference current generating circuit, and in particular to a reference current generator used for programming and erasing of non-volatile memory, that can be utilized in a non-volatile memory in providing a reference current for programming detection and erasure detection of the non-volatile memory.

2. The Prior Arts

Along with the progress of the electronic and information industries, various electronic products of daily usage are developed and produced at a rapid pace. In these electronic products, memory is provided to store data. Presently, the most frequently utilized memory is the non-volatile memory, such as the Flash Memory, which is a kind of non-volatile memory used extensively in various electronic products, such as mobile phone and digital camera.

Usually, the non-volatile memory is composed of a plurality of non-volatile memory cells, such that through controlling the drain current (I_{d}) and the threshold voltage (Vₜ) of a memory cell, the logic state of the memory cell can be controlled. While performing data access of the non-volatile memory, in the process of programming and erasing of memory cells in a non-volatile memory, it will first perform detection of memory cell to make sure that they have been programmed or erased correctly to a predetermined logic state. The detections of programming and erasure of the non-volatile memory are achieved through a current amplifier, such that the drain current (I_{d}) flowing through a memory cell is compared with a reference current (Iᵣ) provided by a reference current generator, so as to determine if the programming or erasure process is indeed completed, or it should be continued.

However, the reference current (Iᵣ) provided by the reference current generator indicates a negative temperature coefficient behavior, such that when temperature is increased, in detecting the programming of a memory cell, the smaller the reference current (Iᵣ), the longer the time is required to finish programming; and when the temperature is decreased, in detecting the erasure of a memory cell, the larger the reference current (Iᵣ), the longer the time is required to finish erasing. Therefore, the time required for writing data into a non-volatile memory can be varied depending on the temperature, while different forms of data may have different and opposite variation tendencies vs temperature, such that it is relatively disadvantageous to the planning and programming of the time required for writing data into a non-volatile memory. Therefore, the performance of data access of the non-volatile memory of the prior art is not quite satisfactory, and it has much room for improvement.

### SUMMARY OF THE INVENTION

In view of the problems and shortcomings of the prior art, the present invention provides a reference current generator used for programming and erasing of the non-volatile memory. Wherein, through the control of a detection point of data write-in, the variation due to temperature is reduced, thus being able to reduce significantly the time variations of data write-in, and enabling planning and programming effectively the time required for data write-in for the non-volatile memory.

A major objective of the present invention is to provide a reference current generator used for programming and erasing of a non-volatile memory. Wherein, a reference voltage of negative temperature coefficient and a reference voltage of positive temperature coefficient are utilized to compensate the negative temperature coefficient of the threshold voltage, such that during detection, the sensitivity of the reference current to temperature for the current flowing through a current detection amplifier can be significantly reduced, and the difference of times required for programming and erasing processes can also be reduced drastically under various operation temperatures.

Another object of the present invention is to provide a reference current generator used for programming and erasing of the non-volatile memory, that is simple in circuit design and construction, thus it can be integrated easily with the non-volatile memory and be used in various electronic products.

In order to achieve the above mentioned objective, the present invention provides a reference current generator used for programming and erasing of the non-volatile memory, comprising: a self-biasing reference generator, a voltage converter, and a reference current source. The self-biasing reference generator includes a first current mirror, and a second current mirror, such that the first current mirror is used to generate a first reference voltage of negative temperature coefficient, and the second current mirror is used to generate a second reference voltage of positive temperature coefficient. The first reference voltage is received by the voltage converter connected electrically to the self-biasing reference generator. The voltage converter generates a third reference voltage, and the second reference voltage and the third reference voltage are received by a reference current source connected electrically to the self-biasing reference generator and the voltage converter respectively, such that the reference current sources generate a reference current.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a system block diagram of a reference current generator used for programming and erasing of the non-volatile memory according to the present invention;

FIG. 2 is a circuit diagram of a reference current generator used for programming and erasing of the non-volatile memory according to the present invention; and

FIG. 3 is a schematic diagram of a reference current generator incorporated into a non-volatile memory according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

The present invention provides a reference current generator used for programming and erasing of the non-volatile memory, which is realized through an optimized circuit design. Wherein, reference voltages of negative temperature coefficient and positive temperature coefficient are used to compensate the negative temperature coefficient of threshold voltage of a transistor, so as to generate reference current of low sensitivity used for programming detection and erasure detection, reduce the time required for programming and erasure in various temperatures, and improve and enhance significantly the planning and programming of the data write-in time of the non-volatile memory. In the following, the technical characteristics of the present invention are described in detail through the preferred Embodiments.

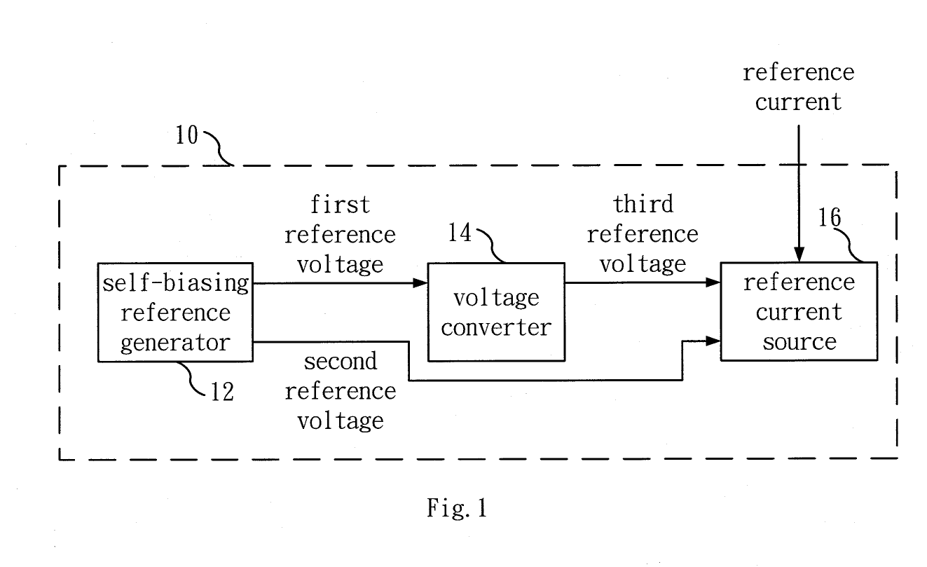

Refer to FIG. 1 for a system block diagram of a reference current generator used for programming and erasing of the non-volatile memory according to the present invention. As shown in FIG. 1, the reference current generator 10 used for programming and erasing of the non-volatile memory comprises: a self-biasing reference generator 12, which generates a first reference voltage of negative temperature coefficient, and a second reference voltage of positive temperature coefficient. A voltage converter 14 is connected electrically to the self-biasing reference generator 12, and is used to receive the first reference voltage and generates a third reference voltage. The temperature coefficient of the third reference voltage is less than temperature coefficient of the first reference voltage. A reference current source 16 is connected electrically to the self-biasing reference generator 12 and the voltage converter 14 respectively, and is used to receive the second reference voltage and the third reference voltage, and generate a reference current required for programming detection and erasure detection of the non-volatile memory.

In the above description, the system structure of the present invention is explained, and in the following, the circuit diagram of the self-biasing reference generator 12, the voltage converter 14, and reference current source 16 in the reference current generator 10 will be described in detail.

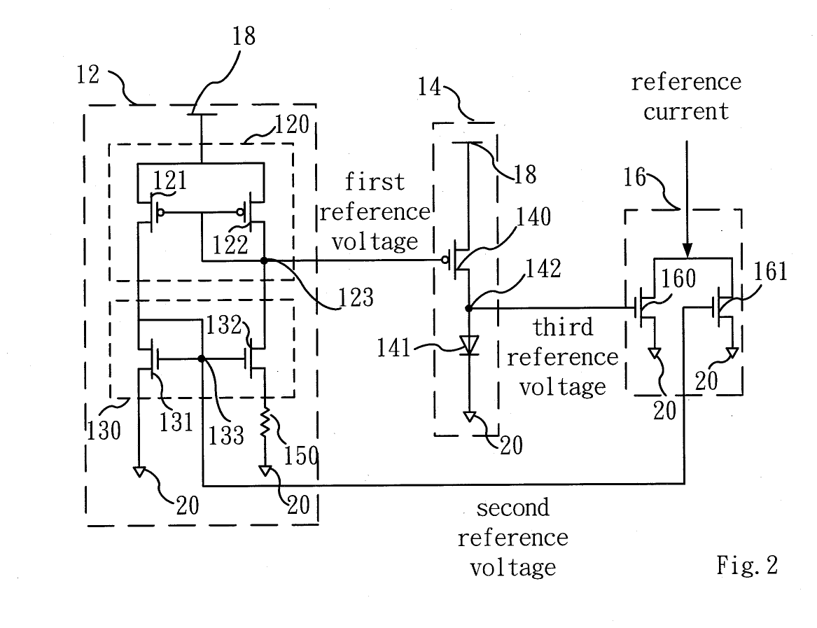

Refer to FIG. 2 for a circuit diagram of a reference current generator used for programming and erasing of the non-volatile memory according to the present invention, refer also to FIG. 1. As shown in FIGS. 1 and 2, the self-biasing reference generator 12 is composed of a first current mirror 120 and a second current mirror 130. The first current mirror 120 includes a first p-channel FET 121 and a second p-channel FET 122 of the same size. The second current mirror 130 includes a first n-channel FET 131 and a second n-channel FET 132 of different sizes. The size of FET 132 is greater than that of FET 131. The source electrodes of the first and second p-channel FET's 121 and 122 are coupled to the first power supply 18 of high voltage. The drain electrodes of the first and second p-channel FET's 121 and 122 are coupled to the drain electrodes of the corresponding first and second n-channel FET's 131 and 132. The source electrode of the first n-channel FET 131 is coupled to the second power supply 20 of ground potential. The source electrode of the second n-channel FET 132 is coupled to the second power supply 20 through connecting to a resistor 150. The gate electrodes of the first and second p-channel FET's 121 and 122 are coupled to each other, and are coupled to the drain electrode of the second p-channel FET 122 and the drain electrode of the second n-channel FET 132 to form a first node 123. The first reference voltage generated by the first p-channel FET 121 is output from the first node 123. The gate electrodes of the first and second n-channel FET's 131 and 132 are connected to each other, and are coupled to the drain electrode of the first p-channel FET 121 and the drain electrode of the first n-channel FET 131 to form a second node 133. The second reference voltage generated by the first n-channel FET 131 is output from the second node 133.

The first reference voltage is input to the voltage converter 14 connected electrically to the self-biasing reference generator 12. The voltage converter 14 is composed of a third p-channel FET 140 and a diode 141 connected in series. The source electrode of the third p-channel FET 140 is coupled to the first power supply 18, and its drain electrode is connected to the anode of a diode 141 to form a third node 142, and the cathode of the diode 141 is coupled to the second power supply 20. The gate electrode of the third p-channel FET 140 is connected electrically to the first node 123, and is used to receive the first reference voltage generated by the first p-channel FET 121, and the third reference voltage is output from the third node 142.

The second reference voltage output from the second node 133 and the third reference voltage output from the third node 142 are received by a reference current source 16. The reference current source 16 is formed by the third n-channel FET 160 and the fourth n-channel FET 161 connected in parallel. The drain electrodes of the third and fourth n-channel FET's 160 and 161 are connected to each other, the source electrodes of the third and fourth n-channel FET's 160 and 161 are connected to the second power supply 20, and the gate electrodes of the third and fourth n-channel FET' 160 and 161 are connected respectively to third node 142 and the second node 133, to receive the third reference voltage and the second reference voltage, so as to compensate the negative temperature coefficient of the threshold voltage through the third reference voltage of negative temperature coefficient and the second reference voltage of positive temperature coefficient, thus generating a reference current of low sensitivity at the connection point of the drain electrodes of the third and fourth n-channel FET's 160 and 161. The temperature coefficient of this reference current is less than the temperature coefficient of the current flowing through the third p-channel FET 140 and the diode 141 connected in series.

In the above description, the circuit diagram of the reference current generator used for programming and erasing of the non-volatile memory is explained in detail. In the following, details are described as to how the reference current generated by a reference current generator 10 is supplied to a non-volatile memory to proceed with programming detection and erasure detection.

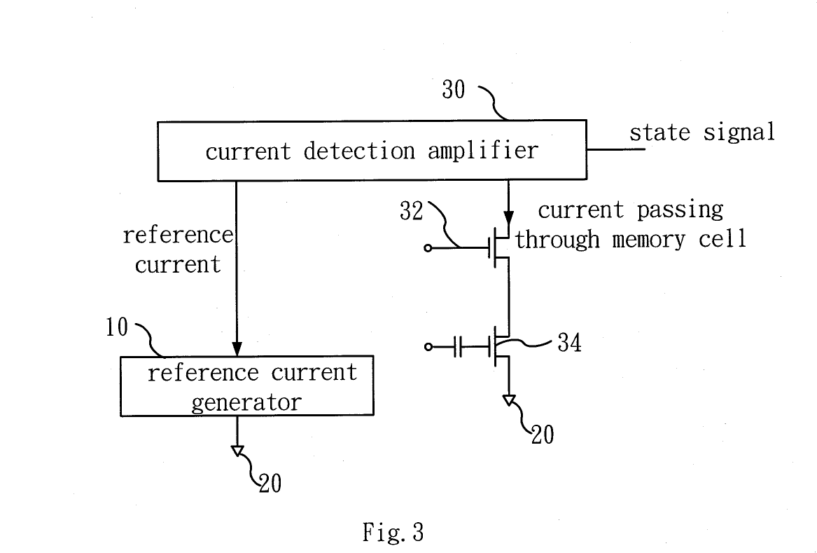

Refer to FIG. 3 for a schematic diagram of a reference current generator incorporated into a non-volatile memory according to the present invention, also refer to FIG. 1. As shown in FIGS. 1 and 3, a current detection amplifier 30 is connected to a reference current generator 10, and a memory cell 34 is connected to the current detection amplifier 30 through connecting to a bit line selection device 32. While performing a routine programming detection in a programming process, the reference current is preset to a maximum preset current value fulfilling the programming requirement for a current flowing through the memory cell; and when the current flowing through the memory cell is less than or equal to the maximum preset current value, the current detection amplifier 30 will output a state signal of logic 0, hereby terminating the programming immediately, otherwise, the programming process will be continued.

While performing a routine erasure detection in an erasure process, the reference current is preset to a minimum preset current value fulfilling the erasure requirement for a current flowing through the memory cell; and when the current flowing through the memory cell is equal to or greater than this minimum preset current value, the current detection amplifier 30 will output a state signal of logic 1, hereby terminating the erasure immediately, otherwise, the erasure process will be continued.

Through the description of the Embodiments mentioned above, it can be known that, in the present invention, the third reference voltage of negative temperature coefficient and the second reference voltage of positive temperature coefficient are utilized to compensate the threshold voltage of a transistor, so as to make the reference current produced by the reference current generator 10 is of low sensitivity, reduce the difference of the times required for the programming and erasure of the non-volatile memory due to temperature variations, and improve the planning and programming of the data write-in time of the non-volatile memory. In addition, the reference current produced by the reference current generator 10 can also be used as the reference current required by the current detection amplifier 30 while performing data reading.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A reference current generator used for programming and erasing of a non-volatile memory, comprising:
a self-biasing reference generator, used to generate a first reference voltage and a second reference voltage;
a voltage converter, connected electrically to said self-biasing reference generator, for receiving said first reference voltage and generating a third reference voltage; and
a reference current source, connected electrically to said self-biasing reference generator and said voltage converter respectively for receiving said second reference voltage and said third reference voltage in generating a reference current.

2. The reference current generator used for programming and erasing of a non-volatile memory as claimed in claim 1, wherein said self-biasing reference generator comprises:
a first current mirror, containing a first p-channel FET and a second p-channel FET, said first p-channel FET is connected electrically to said second p-channel FET, so as to generate said first reference voltage, said first reference voltage is of a negative temperature coefficient; and
a second current mirror, connected electrically and stacked up with said first current mirror, and containing a first n-channel FET and a second n-channel FET, said first n-channel FET and said second n-channel FET are connected electrically to each other, so as to generate said second reference voltage, said second reference voltage is of a positive temperature coefficient.

3. The reference current generator used for programming and erasing of a non-volatile memory as claimed in claim 1, wherein said voltage converter comprises:
a third p-channel FET, connected electrically to said self-biasing reference generator for receiving said first reference voltage; and
a diode, connected electrically to said third p-channel FET, so as to generate said third reference voltage.

4. The reference current generator used for programming and erasing of a non-volatile memory as claimed in claim 1, wherein said reference current source comprises:
a third n-channel FET, connected electrically to said voltage converter, and is used to receive said third reference voltage; and
a fourth n-channel FET, connected in parallel with said third n-channel FET, and is used to receive said second reference voltage and generate said reference current.

5. The reference current generator used for programming and erasing of a non-volatile memory as claimed in claim 1, wherein a temperature coefficient of said third reference voltage is less than said temperature coefficient of said first reference voltage.

6. The reference current generator used for programming and erasing of a non-volatile memory as claimed in claim 3, wherein said temperature coefficient of said reference current is less than said temperature coefficient of a current flowing through said third p-channel FET and said diode connected in series.

7. The reference current generator used for programming and erasing of a non-volatile memory as claimed in claim 1, wherein said reference current is said reference current of a current detection amplifier, for detection of programming and detection of erasure of said memory.

8. The reference current generator used for programming and erasing of a non-volatile memory as claimed in claim 2, wherein sizes of said first p-channel FET and said second p-channel FET are same, while said sizes of said first n-channel FET and said second n-channel FET are different.

9. The reference current generator used for programming and erasing of a non-volatile memory as claimed in claim 2, further comprising: a resistor, connected electrically with said second current mirror.

10. The reference current generator used for programming and erasing of a non-volatile memory as claimed in claim 1, further comprising: a first power supply and a second power supply, coupled to said self-biasing reference generator, said voltage converter, and said reference current source.
